(19) United States
(12) Patent Application Publication
(10) Pub. No.: US 2014/0141619 A1
(43) Pub. Date: May 22, 2014

(54) CAPACITIVELY COUPLED PLASMA EQUIPMENT WITH UNIFORM PLASMA DENSITY

(71) Applicant: TOKYO ELECTRON LIMITED, Tokyo (JP)

(72) Inventor: Ikuo Sawada, Austin, TX (US)

(73) Assignee: TOKYO ELECTRON LIMITED, Tokyo (JP)

(21) Appl. No.: 13/680,929

(22) Filed: Nov. 19, 2012

(51) Int. Cl. H01L 21/3065; H01J 1/46

(52) U.S. Cl. CPC H01L 21/3065; H01J 1/46
USPC 438/711; 156/345.47; 313/310

(57) ABSTRACT

Techniques disclosed herein include apparatus and processes for generating a plasma having a uniform electron density across an electrode used to generate the plasma. An upper electrode (hot electrode), of a capacitively coupled plasma system can include structural features configured to assist in generating the uniform plasma. Such structural features define a surface shape, on a surface that faces the plasma. Such structural features can include a set of concentric rings having an approximately rectangular cross section, and protruding from the surface of the upper electrode. Such structural features can also include nested elongated protrusions having a cross-sectional size and shape, with spacing of the protrusions selected to result in a system that generates a uniform density plasma.

### FIELD OF INVENTION

This disclosure pertains to plasma processing of workpieces, including plasma processing using capacitively coupled plasma systems.

### BACKGROUND OF THE INVENTION

In a semiconductor device manufacturing process, plasma processes such as etching, sputtering, CVD (chemical vapor deposition) and the like are routinely performed on a substrate to be processed, e.g., a semiconductor wafer. Among plasma processing apparatuses for carrying out such plasma processes, capacitively coupled parallel plate plasma processing apparatuses are widely used.

In capacitively coupled parallel plate plasma processing apparatus, a pair of parallel plate electrodes (an upper electrode and a lower electrode) is disposed in a chamber, and a processing gas is introduced into the chamber. By applying radio frequency (RF) electric power to at least one of the electrodes, a high-frequency electric field is formed between the electrodes resulting in a plasma of the processing gas being generated by means of the high-frequency electric field. Subsequently, a plasma process is performed on a wafer by using or manipulating the plasma.

### SUMMARY OF THE INVENTION

Plasma etching of semiconductor wafers is commonly executed using a parallel plate capacitively coupled plasma tool. The semiconductor industry is moving toward making narrower or smaller nodes (critical features) on wafers, as well as using larger wafer sizes. For example, the industry is transitioning from working with 300 mm diameter wafers to 450 mm diameter wafers. With smaller node sizes and larger wafers, the macroscopic and microscopic uniformity of plasma and radicals becomes increasingly important to avoid defects in treated wafers.

In capacitively coupled plasma (CCP), a significant challenge is plasma non-uniformity. It is becoming more desirable to use Very High Frequency plasma (30-300 MHz) in the wafer process, and Radio Frequency (RF) plasma (3-30 MHz) in the flat panel display process. Such higher frequency plasmas, however, tend to be non-uniform at least in part due to a standing wave created in the plasma.

Conventional attempts at addressing non-uniformity of CCP systems include using a hot electrode with a Gaussian lens structure, and phase control technologies. These attempts, however, are complicated and expensive.

Techniques disclosed herein include an upper electrode (hot electrode), of a capacitively coupled plasma system, with structural features configured to assist in generating a uniform plasma. Such structural features define a surface shape, on a surface that faces the plasma, that assists in disrupting standing waves and/or prevents standing waves from forming within the plasma space. For example, such structural features can include a set of concentric rings having an approximately rectangular cross section, and protruding from the surface of the upper electrode. The cross sectional size, shape, dimensions, as well as spacing of the rings, are all selected to result in a system that generates a uniform density plasma.

One embodiment includes an electrode plate configured for use in a parallel-plate capacitively coupled plasma processing apparatus. The plasma processing apparatus including a processing chamber that forms a process space to accommodate a target substrate. A processing gas supply unit is included and configured to supply a processing gas into the processing chamber. An exhaust unit, connected to an exhaust port of the processing chamber, vacuum exhausts gas from inside the processing chamber. A first electrode and a second electrode are disposed opposite each other within the processing chamber. The first electrode is an upper electrode and the second electrode is a lower electrode. The second electrode is configured to support the target substrate via a mounting table. A first radio frequency (RF) power application unit is configured to apply a first RF power to the first electrode, and a second RF power application unit is configured to apply a second RF power to the second electrode. The electrode plate is mountable to the first electrode. The electrode plate has a surface area that faces the second electrode when mounted to the first electrode. The surface area is substantially planar and includes a set of concentric rings protruding from the surface area. Each concentric ring has a predetermined cross-sectional shape, and each concentric ring is spaced at a predetermined gap distance from an adjacent concentric ring.

Another embodiment includes a plasma processing apparatus. This can include several components. A processing chamber forms a process space to accommodate a target substrate. A processing gas supply unit is configured to supply a processing gas into the processing chamber. An exhaust unit is connected to an exhaust port of the processing chamber to vacuum-exhaust gas from inside the processing chamber. A first electrode and a second electrode are disposed opposite each other within the processing chamber. The first electrode is an upper electrode and the second electrode is a lower electrode. The second electrode is configured to support the target substrate via a mounting table. The first electrode includes an electrode plate having a surface that faces the second electrode. The surface is substantially planar and has an external boundary of a predetermined shape. The surface includes a set of elongated protrusions. Each elongated protrusion extends a predetermined height from the surface. Each elongated protrusion extends along the planar surface and around a center point of the first electrode. At least a portion of the elongated protrusions have an elongated shape substantially similar to the external boundary of the surface. The set of protrusions is positioned on the surface such that a portion of the protrusions are surrounded by at least one other protrusion. Each given elongated protrusion can be positioned a predetermined distance from an adjacent elongated protrusion. A first radio frequency (RF) power application unit can be configured to apply a first RF power to the first electrode.

Another embodiment includes a method for generating a uniform plasma for processing a substrate using a plasma processing apparatus. The plasma processing apparatus including a vacuum-evacuable processing chamber, a lower electrode disposed in the processing chamber and serving as a mounting table for a target substrate, an upper electrode disposed to face the lower electrode in the processing chamber, and a first radio frequency (RF) power supply connected to the upper electrode. The first RF power supplies a first RF power to the upper electrode. A target substrate is loaded into the processing chamber and mounted on the lower electrode. An initial gas is evacuated from the processing chamber. A processing gas is supplied into the processing chamber. A plasma is generated from the processing gas by applying the first RF power to the upper electrode. The upper electrode has a surface area that faces the second electrode. The surface area is substantially planar and includes a set of concentric rings protruding from the surface area, the set of concentric rings is located at a predetermined spacing distribution, each concentric ring has a predetermined cross-sectional shape.

Of course, the order of discussion of the different steps as described herein has been presented for clarity sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present invention can be embodied and viewed in many different ways.

Note that this summary section does not specify every embodiment and/or incrementally novel aspect of the present disclosure or claimed invention. Instead, this summary only provides a preliminary discussion of different embodiments and corresponding points of novelty over conventional techniques. For additional details and/or possible perspectives of the invention and embodiments, the reader is directed to the Detailed Description section and corresponding figures of the present disclosure as further discussed below.

### BRIEF DESCRIPTION OF THE DRAWINGS

A more complete appreciation of various embodiments of the invention and many of the attendant advantages thereof will become readily apparent with reference to the following detailed description considered in conjunction with the accompanying drawings. The drawings are not necessarily to scale, with emphasis instead being placed upon illustrating the features, principles and concepts.

FIG. 1 is a cross-sectional view showing a schematic configuration of a plasma processing apparatus in accordance with embodiments disclosed herein.

FIG. 2 is a side cross-sectional view of an upper electrode according to embodiments disclosed herein.

FIG. 3 is a bottom view of an upper electrode according to embodiments disclosed herein.

FIG. 4 is an enlarged side cross-sectional view of an upper electrode according to embodiments disclosed herein.

FIG. 5 is a perspective cross-sectional view of an upper electrode according to embodiments disclosed herein.

FIGS. 6A-6D show side cross-sectional views of example upper electrode protrusions according to embodiments disclosed herein.

FIGS. 7A and 7B show example side cross-sectional views of shapes of upper electrodes according to embodiments disclosed herein.

FIGS. 8A and 8B are bottom views of upper electrodes showing various protrusion patterns.

FIGS. 9A and 9B are line plots of electron density without using embodiments herein.

FIGS. 10A and 10C are contour plots of electron density without using embodiments herein.

FIGS. 10B and 10D are contour plots of electron density results according to embodiments herein.

FIG. 11 is a side cross-sectional view of an upper electrode according to embodiments disclosed herein.

FIG. 12 is a bottom view of an upper electrode according to embodiments disclosed herein.

### DETAILED DESCRIPTION OF SEVERAL EMBODIMENTS

In the following description specific details are set forth, such as a particular geometry of a processing system and descriptions of various components and processes used therein. It should be understood, however, that the invention may be practiced in other embodiments that depart from these specific details, and that such details are for purposes of explanation and not limitation. Embodiments disclosed herein will be described with reference to the accompanying drawings. Similarly, for purposes of explanation, specific numbers, materials, and configurations are set forth in order to provide a thorough understanding. Nevertheless, embodiments may be practiced without such specific details. Components having substantially the same functional constructions are denoted by like reference characters, and thus any redundant descriptions may be omitted.

Various techniques will be described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “target substrate” as used herein generically refers to the object being processed in accordance with the invention. The substrate may include any material portion or structure of a device, particularly a semiconductor or other electronics device, and may, for example, be a base substrate structure, such as a semiconductor wafer, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description below may reference particular types of substrates, but this is for illustrative purposes only.

Techniques disclosed herein include a plasma processing system and accompanying electrode plate structured to enable uniform plasma generation. The electrode plate has a surface that faces the plasma generation space, and this plasma-facing surface includes structures that promote plasma uniformity, even when using Very High Frequency (VHF) RF (radio frequency) power to create the plasma. Such surface structures can include raised concentric rings, nested loops, or other protrusions that provide a radial barrier. Each ring, from a set of concentric rings, can have a cross-sectional height, cross-sectional width, and cross-sectional shape, as well as spacing from adjacent rings, designed to promote both macroscopic and microscopic plasma uniformity.

There exist multiple different plasma processing apparatuses using different approaches to create plasma. For example, various approaches can include inductively coupled plasma (ICP), radial line slot antenna (RLSA), and capacitively coupled plasma (CCP), among others. For convenience, embodiments presented herein will be described in the context of a parallel plate capacitively coupled plasma (CCP) system, though other approaches using electrodes can also be used with various embodiments.

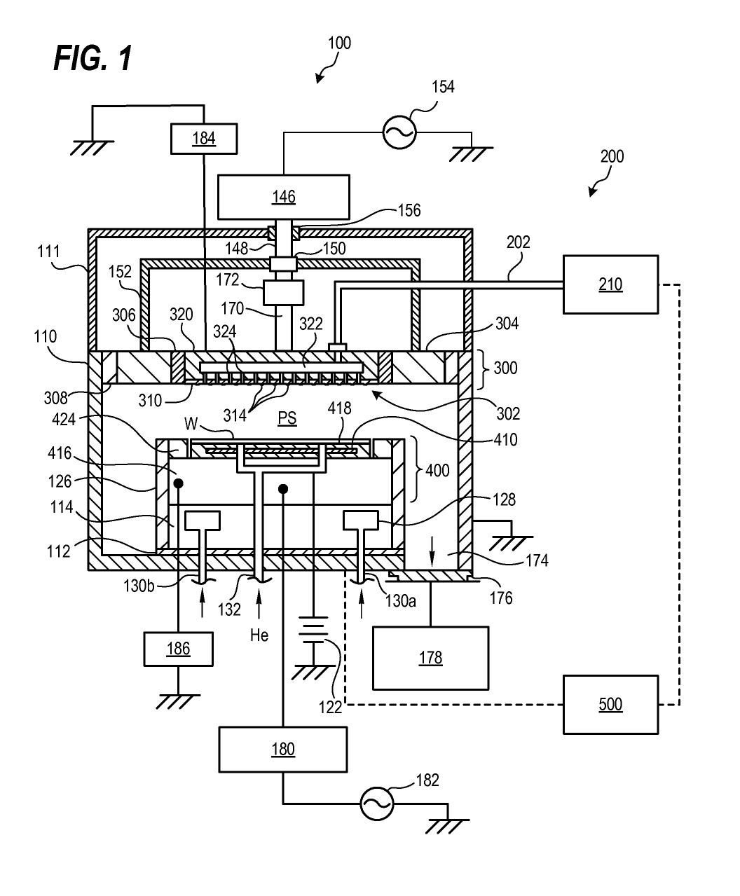

FIG. 1 is a cross sectional view showing a schematic configuration of a plasma processing apparatus in accordance with embodiments herein. The plasma processing apparatus 100 in FIG. 1 is a capacitively coupled parallel plate plasma etching apparatus having an upper electrode with a pattern of protrusions or structures projecting from the upper electrode into the plasma space. Note that techniques herein can be used with other plasma processing apparatuses such as for plasma cleaning, plasma polymerization, plasma assisted chemical vapor deposition, and so forth.

More specifically, the plasma processing apparatus 100 has a processing chamber 110 defining a processing vessel providing a process space having, for example, a substantially cylindrical shape. The processing vessel can be formed of, e.g., an aluminum alloy, and can be electrically grounded. An inner wall of the processing vessel can be coated with alumina (Al.sub.2O.sub.3), yttria (Y.sub.2.Osub.3), or other protectant. A susceptor 416 forms part of a lower electrode 400 (lower electrode assembly) as an example of a second electrode acting as a mounting table for mounting a wafer W thereon as a substrate. Specifically, the susceptor 416 is supported on a susceptor support 114, which is provided at substantially the center of the bottom in the processing chamber 110 via an insulating plate 112. The susceptor support 114 can be cylindrical. The susceptor 416 can be formed of, e.g., an aluminum alloy.

Susceptor 416 is provided thereon with an electrostatic chuck 418 (as part of the lower electrode assembly) for holding the wafer W. The electrostatic chuck 418 is provided with an electrode 410. Electrode 410 is electrically connected with a DC (direct current) power supply 122. The electrostatic chuck 418 attracts the wafer W thereto via a Coulomb force generated when DC voltage from the DC power supply 122 is applied to the electrode 410.

A focus ring 424 is provided on an upper surface of the susceptor 416 to surround the electrostatic chuck 418. A cylindrical inner wall member 126 formed of, e.g., quartz, is attached to the outer peripheral side of the electrostatic chuck 418 and the susceptor support 114. The susceptor support 114 includes an annular coolant path 128. The annular coolant path 128 communicates with a chiller unit (not shown), installed outside the processing chamber 110, for example, via lines 130a and 130b. Annular coolant path 128 is supplied with coolant (cooling liquid or cooling water) circulating through the lines 130a and 130b. Accordingly, the temperature of the wafer W mounted on/above the susceptor 416 can be controlled.

A gas supply line 132, which passes through the susceptor 416 and the susceptor support 114, is configured to supply heat transfer gas to an upper surface of the electrostatic chuck 418. A heat transfer gas (backside gas) such as He (helium) can be supplied between the wafer W and the electrostatic chuck 418 via the gas supply line 132 to assist in heating wafer W.

An upper electrode 300 (that is, an upper electrode assembly), which is an example of a first electrode, is provided vertically above the lower electrode 400 to face the lower electrode 400 in parallel. The plasma generation space or plasma space (PS) is defined between the lower electrode 400 and the upper electrode 300. The upper electrode 300 includes an inner upper electrode 302 having a disk shape, and an outer upper electrode 304 can be annular surrounding the outside of the inner upper electrode 302. The inner upper electrode 302 also functions as a processing gas inlet for injecting a specific amount of processing gas towards the plasma generation space PS on the wafer W mounted on the lower electrode 400. The upper electrode 300 thereby forms a shower head.

More specifically, the inner upper electrode 302 includes electrode plate 310 (which is typically circular) having a plurality of gas injection openings 324 and protrusions 314. The protrusions 314 and configurations thereof will be described later in more detail. Inner upper electrode 302 also includes an electrode support 320 detachably supporting the upper side of the electrode plate 310. The electrode support 320 can be formed in the shape of a disk having substantially the same diameter as the electrode plate 310 when electrode plate 310 is circular in shape. In alternative embodiments, electrode plate 310 can be square, rectangular, polygonal, etc. The electrode support 320 can be formed of, e.g., aluminum, and can include a buffer chamber 322. Buffer chamber 322 is used for diffusing gas and has a space having a disk shape. The processing gas from a gas supply system 200 is introduced into the buffer chamber 322. The processing gas can then move from the buffer chamber 322 to the gas injection openings 324 at a lower surface thereof. The inner upper electrode then essentially provides a showerhead electrode.

A dielectric 306, having a ring shape, is interposed between the inner upper electrode 302 and the outer upper electrode 304. An insulating shield member 308, which has a ring shape and is formed of, e.g., alumina, is interposed between the outer upper electrode 304 and the inner peripheral wall of the processing chamber 110 in an air tight manner.

The outer upper electrode 304 is electrically connected with a first high-frequency power supply 154 via a power feeder 152, a connector 150, an upper power feed rod 148, and a matching unit 146. The first high-frequency power supply 154 can output a high-frequency voltage having a frequency of 40 MHz (megahertz) or higher (e.g. 60 MHz), or can output a very high frequency (VHF) voltage having a frequency of 30-300 MHz. The power feeder 152 can be formed into, e.g., a substantially cylindrical shape having an open lower surface. The power feeder can be connected to the outer upper electrode 304 at the lower end portion thereof. The power feeder 152 is electrically connected with the lower end portion of the upper power feed rod 148 at the center portion of the upper surface thereof by means of the connector 150. The upper power feed rod 148 is connected to the output side of the matching unit 146 at the upper end portion thereof. The matching unit 146 is connected to the first high-frequency power supply 154, and can match load impedance with the internal impedance of the first high-frequency power supply 154. Note, however, that outer upper electrode 304 is optional and embodiments can function with a single upper electrode.

Power feeder 152 is covered on the outside thereof by a ground conductor 111, which can be cylindrical having a sidewall whose diameter is substantially the same as that of the processing chamber 110. The ground conductor 111 is connected to the upper portion of a sidewall of the processing chamber 110 at the lower end portion thereof. The upper power feed rod 148 passes through the center portion of the upper surface of the ground conductor 111. An insulating member 156 is interposed at the contact portion between the ground conductor 111 and the upper power feed rod 148.

The electrode support 320 is electrically connected with the lower power feed rod 170 on the upper surface thereof. The lower power feed rod 170 is connected to the upper power feed rod 148 via the connector 150. The upper power feed rod 148 and the lower power feed rod 170 form a power feed rod for supplying the high-frequency electric power from the first high-frequency power supply 154 to the upper electrode 300 (collectively referred to as “power feed rod”). A variable condenser 172 is provided in the lower power feed rod 170. By adjusting the capacitance of the variable condenser 172, when the high-frequency electric power is applied from the first high-frequency power supply 154, the relative ratio of an electric field strength formed directly under the outer upper electrode 304 to an electric field strength formed directly under the inner upper electrode 302 can be adjusted.

A gas exhaust port 174 is formed at the bottom portion of the processing chamber 110. The gas exhaust port 174 is connected to a gas exhaust unit 178 that can include, e.g., a vacuum pump, via a gas exhaust line 176. The gas exhaust unit 178 evacuates the inside of the processing chamber 110 to thereby depressurize the inner pressure thereof up to the desired degree of vacuum. The susceptor 416 can be electrically connected with a second high-frequency power supply 182 via a matching unit 180. The second high-frequency power supply 182 can output a high-frequency voltage in a range from 2 MHz to 20 MHz, e.g., 2 MHz.

The inner upper electrode 302 of the upper electrode 300 is electrically connected with an LPF (low pass filter) 184. The LPF 184 blocks high frequencies from the first high-frequency power supply 154 while passing low frequencies from the second high-frequency power supply 182 to the ground. Meanwhile, the susceptor 416, forming part of the lower electrode, is electrically connected with an HPF (high pass filter) 186. The HPF 186 passes high frequencies from the first high-frequency power supply 154 to the ground. The gas supply system 200 supplies gas to the upper electrode 300. The gas supply system 200 includes, e.g., a processing gas supply unit 210 supplying a processing gas for performing specific processes, such as film-forming, etching and the like, on the wafer, as shown in FIG. 1. The processing gas supply unit 210 is connected with a processing gas supply line 202 forming a processing gas supply path. The processing gas supply line 202 is connected to the buffer chamber 322 of the inner upper electrode 302.

The plasma processing apparatus 100 is connected with a control unit 500 that controls each component of the plasma processing apparatus 100. For example, the control unit 500 controls the DC power supply 122, the first high-frequency (or VHF) power supply 154, the second high-frequency (or VHF) power supply 182, etc. in addition to the processing gas supply unit 210, etc., of the gas supply system 200.

Note that the inner upper electrode 302 includes the electrode plate 310 facing the lower electrode 400, thereby forming parallel plates for a capacitively coupled plasma tool. The electrode support 320 is in contact with a back surface of the electrode plate 310 opposite to the lower electrode 400 (here, the rear surface of the electrode plate), and detachably supports the electrode plate 310. In alternative embodiments, the electrode plate 310 can be integral with the upper electrode 300. Having the electrode plate 310 being detachable, however, is beneficial because plasma is chemically reactive and can erode a surface area that faces the lower electrode. Accordingly, electrode plates can be removed for replacement, or to select an electrode plate of various different types of materials appropriate for a specific type of plasma process.

The upper electrode 300 can also include a cooling plate or mechanism (not shown) to control temperature of the electrode plate 310. The electrode plate 310 can be formed of a conductor or semiconductor material, such as Si, SiC, dopped Si, Aluminum, and so forth.

In operation, the plasma processing apparatus 100 uses the upper and lower electrodes to generate a plasma in the PS. This generated plasma can then be used for processing a target substrate, such as wafer W or any material to be processed, in various types of treatments such as plasma etching, chemical vapor deposition, treatment of glass material and treatment of large panels, etc. For convenience, this plasma generation will be described in the context of etching an oxide film formed on the wafer W. First, the wafer W is loaded into the processing chamber 110 from a load lock chamber (not shown), after a gate valve (not shown), is opened, and is mounted on the electrostatic chuck 418. Then, when the DC voltage is applied from the DC power supply 122, the wafer W is electrostatically attached to the electrostatic chuck 418. After that, the gate valve is closed, and the processing chamber 110 is evacuated to a specific vacuum level by the gas exhaust unit 178.

Thereafter, the processing gas is introduced into the buffer chamber 322 in the upper electrode 300 from the processing gas supply unit 210 via the processing gas supply line 202 while the flow rate thereof is adjusted by, e.g., a mass flow controller. Further, the processing gas introduced into the buffer chamber 322 is uniformly discharged from the gas injection openings 324 of the electrode plate 310 (showerhead electrode) to the wafer W, and then the inner pressure of the processing chamber 110 is maintained at a specific level.

High-frequency electric power in a range from 3 to 150 MHz, e.g., 60 MHz, is applied from the first high-frequency power supply 154 to the upper electrode 300. Thereby, a high-frequency electric field is generated between the upper electrode 300 and the susceptor 116, forming the lower electrode, and the processing gas is dissociated and converted into a plasma. A low frequency electric power in a range from 0.2 to 20 MHz, e.g., 2 MHz, is applied from the second high-frequency power supply 182 to the susceptor 116 forming the lower electrode. In other words, a dual frequency system can be used. As a result, ions in the plasma are attracted toward the susceptor 116, and the anisotropy of etching is increased by ion assist.

A major challenge with capacitively coupled plasma tools is plasma non-uniformity. Certain plasma processes can benefit from using Very High Frequency (VHF) electric power in the range of 30-300 MHz. Such VHF electric power, however, tends to create a non-uniform electric field. At higher frequencies the wavelength decreases while non-uniformity increases, especially as the wavelength becomes relatively small compared to a diameter of the electrode. Such non-uniformity is problematic because it results in non-uniform exposure of the wafer W, which in turn leads to defects in the wafer W.

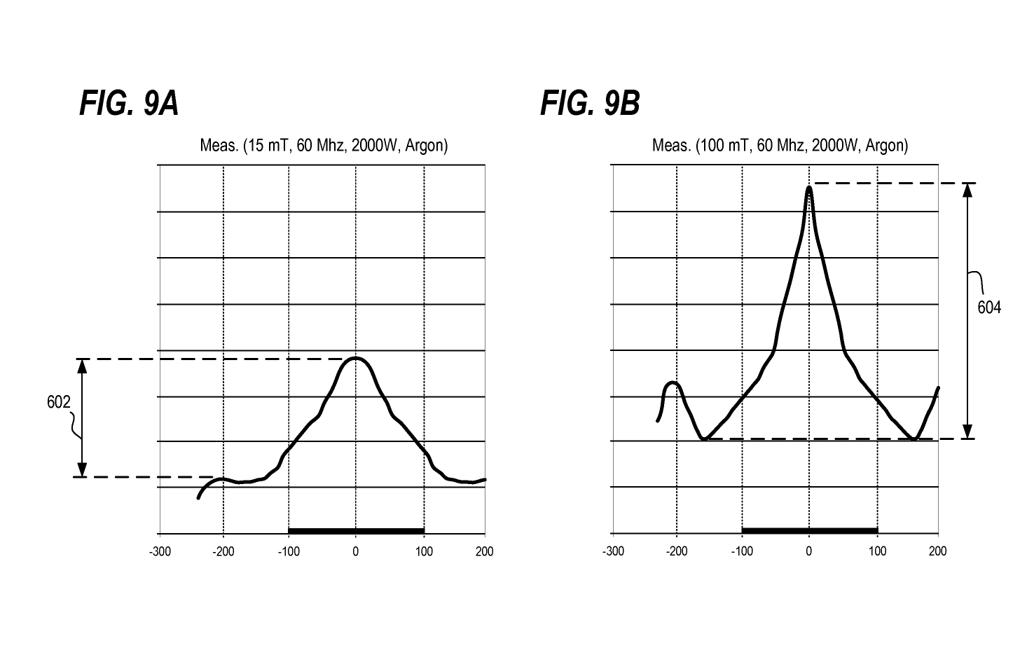

Generating uniform plasma is complicated. In ideal plasma, there is an equal distribution of ions and electrons moving within the plasma. There are different variables at play that can affect plasma uniformity. These variables include power, frequency, pressure, materials, and so forth. One measure of non-uniformity is electron density within the plasma at various locations. FIG. 9A shows a line plot of electron density (plasma intensity) relative to locations on an electrode plate. In this line plot, the X-axis indicates distance from a center point of a wafer (aligned with the electrode plate), with 0 being the center of the wafer. The Y-axis identifies relative electron density. Note that there is a significant electron density difference 602 between the center and the edge of the wafer. There is a sharp center peak, as the electron density in the center of the wafer is about three to four times greater than the electron density at the edge.

Likewise in FIG. 9B there is a similar center peak or center high distribution of electrons. FIG. 9B differs from FIG. 9A in that a higher pressure is used. With higher pressures, there is still a center peak that has about three to four times the electron density at the edge (electron density difference 604), but note that there is also a second peak near the edge of the wafer or electrode at this higher pressure.

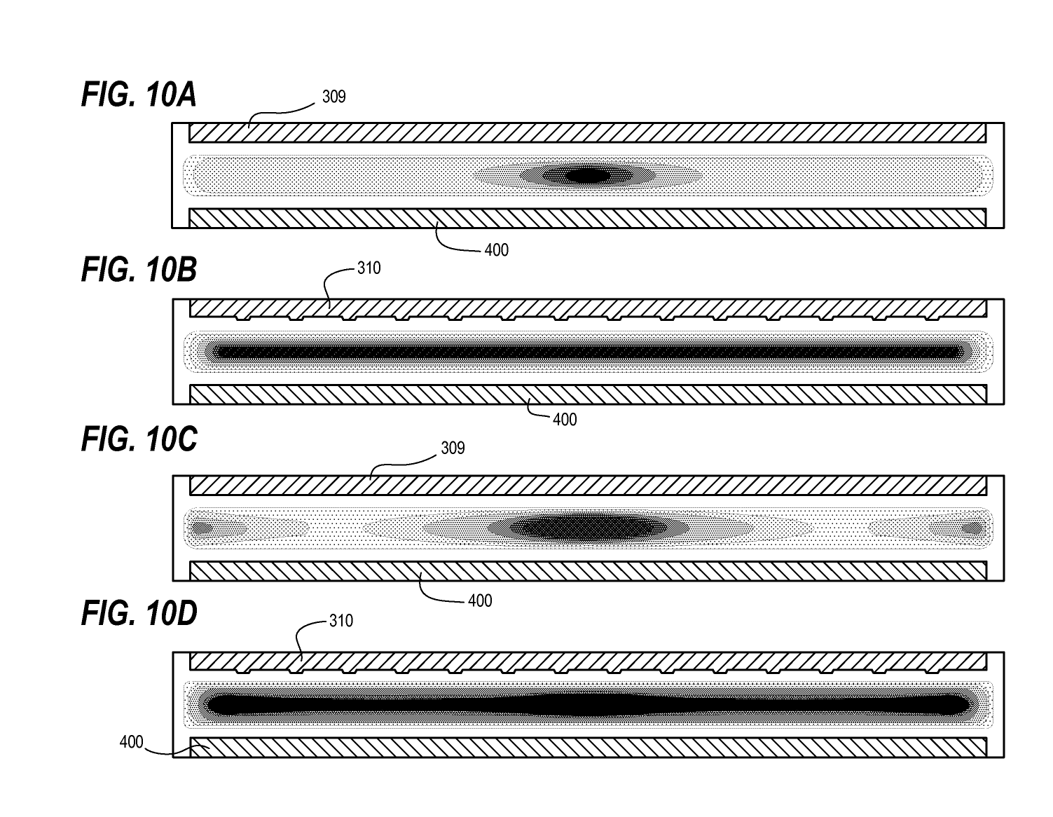

FIG. 10A is a contour illustration showing electron density in a plasma space relative to an upper electrode 309 and lower electrode 400. Note that upper electrode 309 (or electrode plate) has a generally flat surface as with conventional electrode plates. FIG. 10A correlates to FIG. 9A. Darker spaces in the contour plot represent higher electron density. Accordingly, FIG. 10A shows a high electron density in the center of the plasma space, with a relatively low electron density toward the edges of the electrodes. FIG. 10C is similar to FIG. 10A, except that FIG. 100 correlates to FIG. 9B. As such, note that there is a high center electron density, as well as secondary peaks (albeit smaller) on the edges of the plasma space.

Techniques herein have thus been conceived to promote uniform electron density within the plasma, such as by eliminating and/or controlling this wave. Techniques include using one or more structures on electrode plate 310. Such structures are located on a plasma facing surface of electrode plate 310. Such structures can be configured to provide one or more barriers in a radial direction, or rather, from a center point of the electrode plate 310 outward.

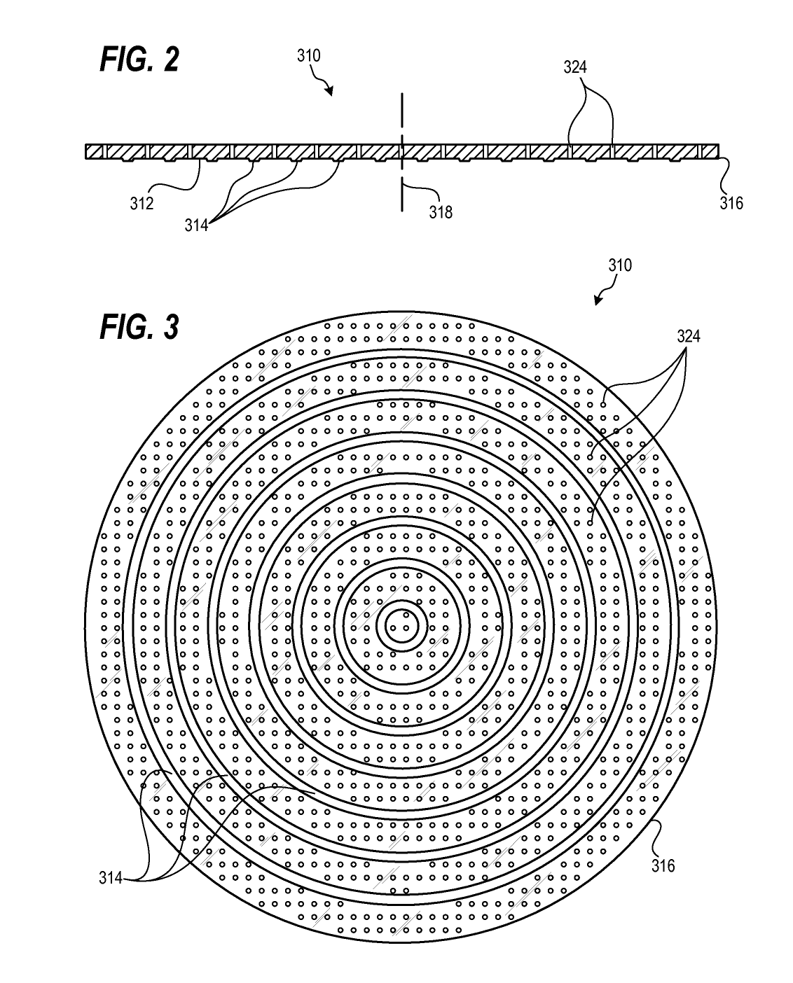

Referring now to FIG. 2, there is illustrated a side cross-sectional view of an example electrode plate 310. On surface area 312 there are multiple protrusions 314. Note that these structures (protrusions) form a type of barrier when moving along surface area 312 from center point 318 towards external boundary 316.

FIG. 3 shows bottom view of electrode plate 310. In this view, protrusions 314 are illustrated as a set of concentric rings centered around center point 318. In some embodiments, the set of concentric rings can have even or equidistant spacing. In other embodiments, the spacing can be variable. The cross sectional size and shape, as well as gap distance between concentric rings, can be based on a plasma wavelength or expected plasma wave length. The number of concentric rings can also vary based on a diameter of the surface area 312. The rings or protrusions 314 can be mounted or affixed (welded, fused, fastened) onto the surface area 312, or can be integral with the electrode plate 310 such as by machining the protrusions or casting the electrode plate.

FIG. 4 is an enlarged cross-sectional view of electrode plate 310. In this view, protrusions 314 are shown as having an approximate rectangular cross-sectional shape, with a round 332 and fillet 334. Such rounding is not required, but can have a beneficial effect on controlling wave propagation. Each protrusion can have a cross-sectional width 336 and a cross-sectional height 338. Adjacent protrusions are separated from each other a gap distance 340. Such a gap distance 340 can be measured from edge, to edge, center to center, or otherwise. Values for these dimensions can be absolute or relative. For example, values can be selected from a particular range of dimension, based on electrode plate diameter, based on a particular etch/deposition process, or based on plasma wavelength of a generated plasma. For VHF plasmas that have a wavelength of one to 10 centimeters, protrusion dimensions and gap distances can be determined based on that wavelength to yield optimal plasma uniformity.

FIG. 5 is an enlarged cross-sectional perspective view of electrode plate 310 showing surface area 312 that faces the plasma space.

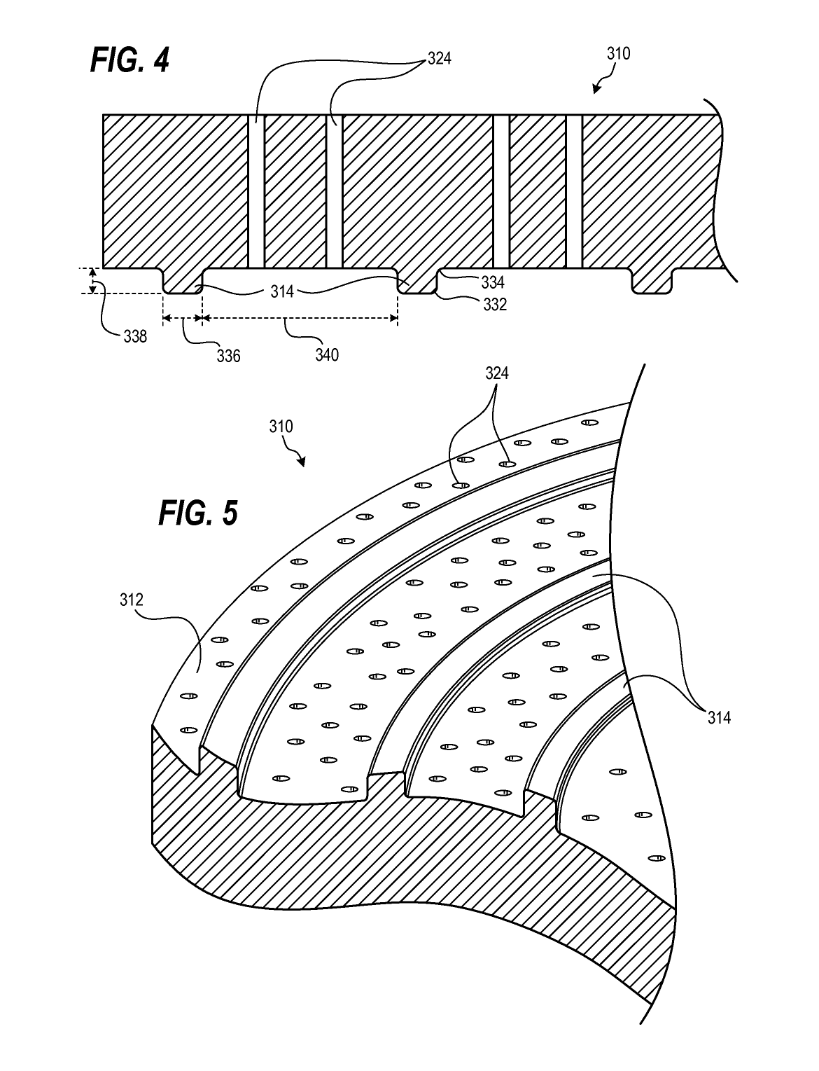

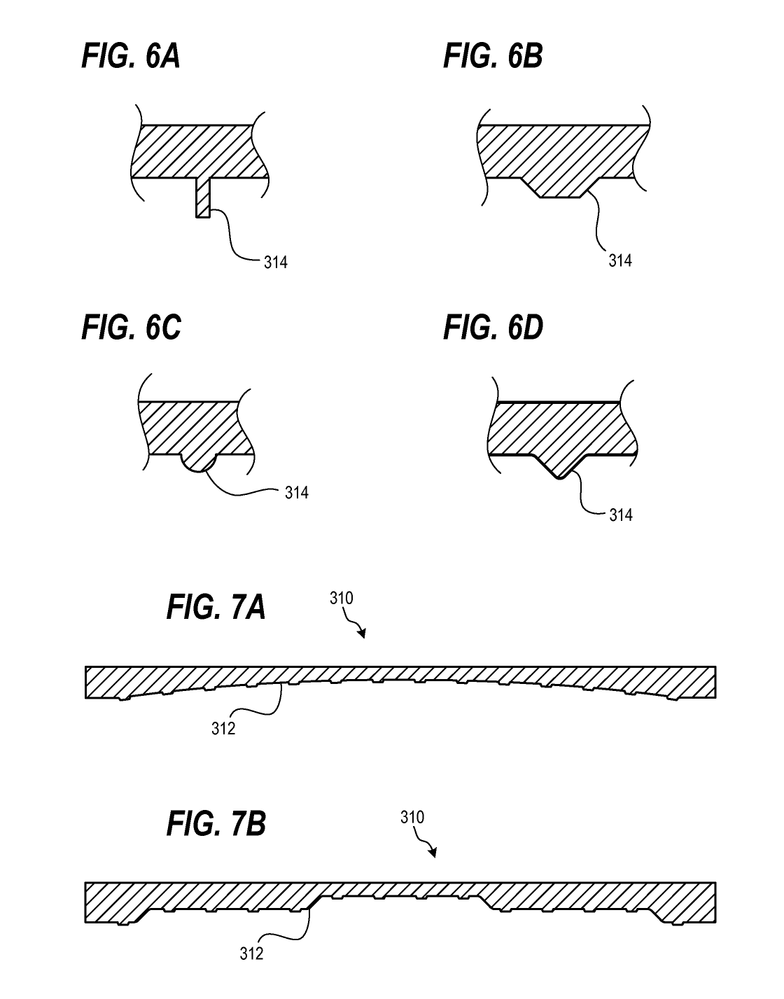

There are various cross-sectional shapes that can be selected for use in embodiments herein. For example, FIG. 6A shows a relatively thin cross-sectional shape such that protrusions 314 are essentially fins projecting from surface area 312. FIG. 6B shows a trapezoidal shape of protrusions 314. In FIG. 6C, protrusion 314 is a rounded or semicircular shape. In FIG. 6D, protrusion 314 is a triangular shape.

In addition to various cross-sectional shapes of protrusions 314, electrode plate 310 can have alternative cross-sectional shapes. For example, FIG. 7A shows electrode plate 310 having a Gaussian lens shape in that surface area 312 has a concave curvature (relative to the plasma space PS). In FIG. 7B, electrode plate has a surface area 312 that is stepped in that different portions of surface area 312 are different vertical distances from lower electrode 400.

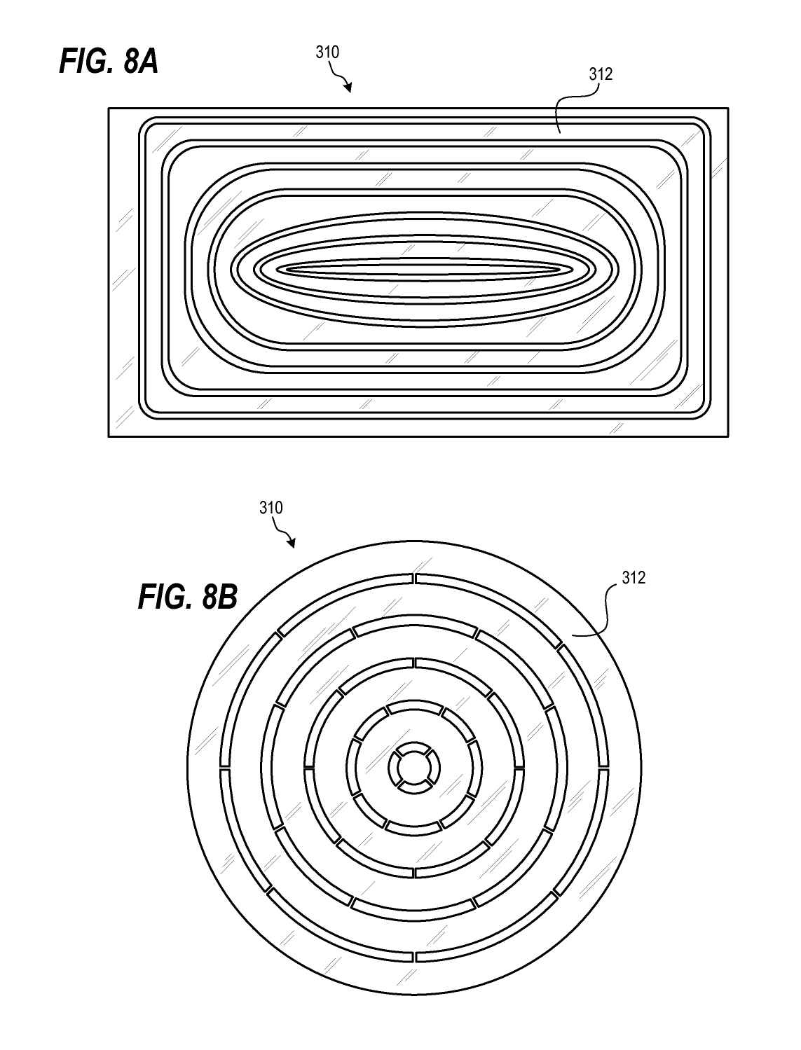

FIG. 8A is a bottom view of an alternative embodiment of electrode plate 310. Instead of a set of concentric rings, FIG. 8A shows electrode plate 310 has having a surface area 312 that is rectangular with rectangular and elliptical elongated protrusions surrounding the center of the electrode plate. In FIG. 8B protrusions 314 are concentric rings that are not continuous, but have openings but such that protrusions 314 still provide a barrier approximately perpendicular to a given radial direction on the surface area 312. In other embodiments, the rings or protrusions are continuous.

With such protrusions on the electrode plate in a corresponding plasma processing apparatus, the plasma processing apparatus can provide a uniform electron density, even at VHF powers. FIG. 10B and FIG. 10D show an example contour plot of electron density in a plasma processing apparatus using an electrode plate 310 having concentric rings or other elongated protrusions. Note that the result of such electrode plate protrusions is a generally uniform electron density across that plasma space. Without techniques herein, plasma non-uniformity can be as high as 200% or more, while techniques herein can provide plasma non-uniformity of less than 10%.

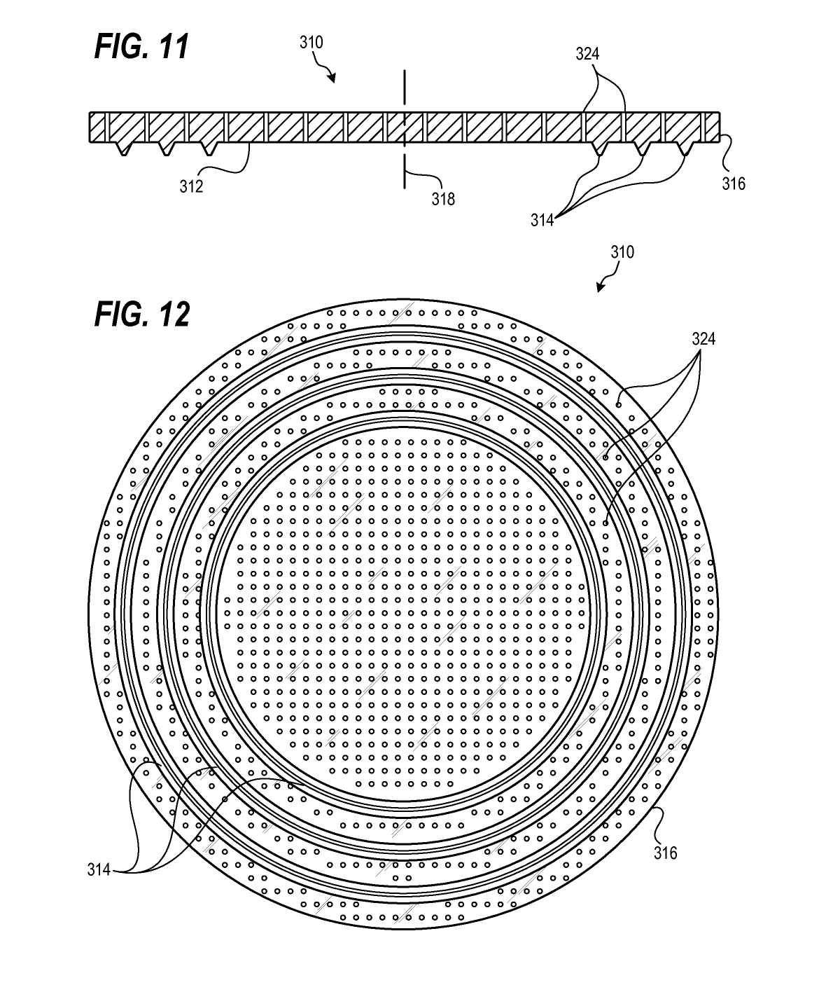

FIGS. 11 and 12 illustrate an alternative example arrangement of electrode plate 310. FIG. 11 is a side cross-sectional view of an example electrode plate 310. FIG. 12 is a bottom view of the electrode plate 310. On surface 312 there are multiple protrusions 314 (such as fins) projecting from the surface or otherwise attached to the surface. Note that protrusions 324 are arranged within an outer portion of surface 312. Thus, an inner circular portion of surface 312 is free from protrusions, while an outer ring-shaped portion of surface 312 (an edge region) includes multiple concentric rings of protrusions 324. Note also that protrusions 314 have an approximately triangular or conical cross-sectional shape. Instead of sidewalls of protrusions 314 being perpendicular to surface 312, sidewalls have an obtuse angle relative to surface 312. For example such an obtuse angle can be between about 100 degrees and 160 degrees from surface 312 to an adjacent sidewall. Having angled sidewalls can further promote plasma uniformity. For example, higher frequency electromagnetic waves traveling near or across surface area 312 can be deflected into a plasma space, thereby increasing uniformity. In this embodiment, a higher frequency RF can be supplied from the upper electrode and a lower RF frequency from a lower electrode, as is typical. This embodiment, however, can also function effectively when applying the higher frequency from the bottom electrode, and a lower frequency from the top electrode.

As is evident, there are various alternative embodiments provided by techniques herein.

One embodiment includes an electrode for use in a plasma processing apparatus. This electrode can be a removable electrode or a more permanent electrode. The electrode includes an electrode plate configured for use in a parallel-plate capacitively coupled plasma processing apparatus. The plasma processing apparatus includes a processing chamber that forms a process space to accommodate a target substrate such as a semiconductor wafer or flat panel. A processing gas supply unit is configured to supply a processing gas into the processing chamber. An exhaust unit is connected to an exhaust port of the processing chamber to vacuum-exhaust gas from inside the processing chamber. A first electrode and a second electrode are disposed opposite each other within the processing chamber. The first electrode being is upper electrode (300) and the second electrode is a lower electrode (400). The second electrode is configured to support the target substrate via a mounting table. A first radio frequency (RF) power application unit is configured to apply a first RF power to the first electrode. This first RF power application unit can include a power supply, or circuitry to receive and apply an external power supply. A second RF power application unit is configured to apply a second RF power to the second electrode. The electrode plate is mountable to the first electrode. The electrode plate has a surface area that faces the second electrode when mounted to the first electrode. The surface area of the electrode plate is substantially planar and includes a set of concentric rings protruding from the surface area. Each concentric ring has a predetermined cross-sectional shape, and each concentric ring is spaced at a predetermined gap distance, such as a particular radial distance, from an adjacent concentric ring.

A cross-sectional height of each concentric ring can be greater than about 0.5 millimeters and less that about 10.0 millimeters. Also, a cross-sectional width of each concentric ring can be greater than about 1.0 millimeters and less than about 20.0 millimeters. The predetermined gap distance can then be greater than about 1.0 millimeters and less that about 50.0 millimeters. Other embodiments have narrower ranges. For example, the cross-sectional height of each concentric ring is greater than about 1.0 millimeters and less that about 3.0 millimeters, with the cross-sectional width of each concentric ring being greater than about 2.0 millimeters and less than about 5.0 millimeters, while the predetermined gap distance is greater than about 6.0 millimeters and less that about 20.0 millimeters.

The first RF power applied can be between 3 MHz and 300 MHz, or between 30 MHz and 300 MHz for VHF applications. Techniques herein can be effective for RF frequencies and lower. A cross-sectional height of each concentric ring, a cross-sectional width of each concentric ring, and the predetermined gap distance can all be selected based on a diameter of the surface area of the electrode plate. For example a different configuration for 300 mm diameter wafers might be used as compared to 450 mm diameter wafers. The cross-sectional shape of each concentric ring can be approximately rectangular. This approximately rectangular cross-sectional shape can have a round with a radius of between 0.2 millimeters and 1.0 millimeters, and have a fillet with a radius of between about 0.2 millimeters and 1.0 millimeters.

In another embodiment, a plasma processing apparatus includes a processing chamber that forms a process space to accommodate a target substrate, a processing gas supply unit configured to supply a processing gas into the processing chamber, an exhaust unit connected to an exhaust port of the processing chamber to vacuum-exhaust gas from inside the processing chamber; a first electrode and a first RF power application unit. The first electrode and a second electrode are disposed opposite each other within the processing chamber. The first electrode is an upper (hot) electrode and the second electrode is a lower electrode. The second electrode is configured to support the target substrate via a mounting table, which can be an electrostatic chuck. The first electrode includes an electrode plate having a surface that faces the second electrode, with this surface being substantially planar and having an external boundary of a predetermined shape. This surface includes a set of elongated protrusions. Each elongated protrusion extends or projects a predetermined height from the surface, each elongated protrusion extends along the planar surface and around a center point of the first electrode. At least a portion of the elongated protrusions have an elongated shape substantially similar to the external boundary of the surface. Thus, for circular electrodes, the elongated protrusions are substantially circular, for elliptical electrodes at least a few of the protrusions are elliptical, and for rectangular electrodes at least a portion of the elongated protrusions are rectangular. This portion can be all or less than all of the set of elongated protrusions. The set of elongated protrusions are positioned on the surface such that a portion of the protrusions are surrounded by at least one other protrusion. In other words, all or some of the elongated protrusions are nested (if rectangular) or concentric (if round). Each given elongated protrusion can be positioned a predetermined distance from an adjacent elongated protrusion. Thus, there can be equal or variable spacing between each elongated protrusion. A first radio frequency (RF) power application unit is configured to apply a first RF power to the first electrode. A second RF power application unit can also be configured to apply a second RF power to the second electrode.

The predetermined height of each protrusion can be greater than about 0.5 millimeters and less that about 10.0 millimeters, with a cross-sectional width of each protrusion being greater than about 1.0 millimeters and less than about 20.0 millimeters, and while a gap distance between adjacent protrusions is greater than about 1.0 millimeters and less that about 50.0 millimeters. Alternatively, the predetermined height of each protrusion is greater than about 1.0 millimeters and less that about 3.0 millimeters, the cross-sectional width being greater than about 2.0 millimeters and less than about 5.0 millimeters, and the gap distance between adjacent protrusions being greater than about 6.0 millimeters and less that about 20.0 millimeters.

Plasma processing can be executed with the first RF power between 3 MHz and 300 MHz, or the first RF power between 30 MHz and 300 MHz. The predetermined height of each protrusion and the cross-sectional width of each protrusion can be selected based on a frequency range of the first RF power such that a plasma generated via the plasma processing apparatus has a substantially uniform electron density across the first electrode. The height can also be determined based on a wavelength of a plasma wave from plasma generated in the process space. At least a portion of the set of elongated protrusions can have a substantially rectangular elongated shape.

The electrode plate can comprise a material selected from the group consisting of aluminum, silicon, and doped silicon. Other materials include stainless steel, carbon, chrome, tungsten, or other semiconductive or conductive material. The electrode plate can include a protective coating.

Other embodiments can include methods for plasma processing using electrodes with protrusions. For example, in a plasma processing apparatus as described above, processing can begin by loading the target substrate into the processing chamber, and mounting the target substrate on the lower electrode. An initial gas from the processing chamber is evacuated. Thus any gas present upon loading the target substrate can be removed. Then processing gas is supplied into the processing chamber. A plasma is generated from the processing gas (such as argon) by applying the first RF power to the upper electrode. This upper electrode has a surface area that faces the second electrode. This surface area is substantially planar and includes a set of concentric rings protruding from the surface area. The set of concentric rings is located at a predetermined spacing distribution, with each concentric ring having a predetermined cross-sectional shape. The process can include using a second RF power supply connected to the lower electrode, the second RF power supply applies a second RF power to the lower electrode, thereby biasing the lower electrode. The first frequency can be adjusted as well as an operating pressure within the processing chamber such that the plasma generated has a specific electron density non-uniformity across the second electrode of less than about 10%.

In alternative embodiments, the number of rings included on the electrode can be based on a diameter of the electrode. Likewise, cross-sectional dimensions of the protrusions can be based on electrode diameter. In some embodiments, an electrode plate for use in treating a 300 mm diameter wafer includes between about 2 and 30 rings, while an electrode plate used for processing 450 mm diameter wafers includes between about 3 and 45 rings. In some embodiments, the gap distance (spacing distance between adjacent rows or rings of protrusions) is smaller than a wavelength or frequency of the plasma wavelength generated within the processing chamber. In other embodiments, dimensions can be based on quarter wavelengths.

In some embodiments, the cross-sectional dimensions and/or fin spacing can be based on a frequency applied to the upper electrode. For example, when plasma is generated by using a frequency of 3-30 MHz applied to the upper electrode, then fin spacing can have a first predetermined fin spacing. Then, when plasma is generated by using a frequency of 30-300 MHz applied to the upper electrode, a second predetermined fin spacing is used, wherein the second predetermined fin spacing is smaller than the first predetermined fin spacing. Applying higher frequencies to the upper electrode can result in plasma wavelengths significantly smaller than the electrode plate. For example, with applied frequencies between 3-30 MHz, a generated plasma can have wavelengths of 15 centimeters or more, while with applied frequencies of between 30-300 MHz (or more), a generated plasma can have wavelengths less than 15 cm, and even less than 1-3 cm due to the effect of higher harmonics. Thus, dimensions of the upper electrode plate can be based on tailored applied power having a particular frequency.

Selecting an optimal cross-sectional height of protrusions is beneficial. With a relatively small protrusion height, there can still be a center high electron density. If the protrusions, however, are too high, the electron density will remain edge high. Typical spacing between the upper electrode and the lower electrode (spacing between the surface of the electrode place and the surface of a target substrate) can be between about 10 and 100 mm. Typical power ranges for the upper electrode are between 50 watts and 20,000 watts, while pressure can range from 1 mTorr (millitorr) to 10 Torr.

Although only certain embodiments of this invention have been described in detail above, those skilled in the art will readily appreciate that many modifications are possible in the embodiments without materially departing from the novel teachings and advantages of this invention. Accordingly, all such modifications are intended to be included within the scope of this invention.

1. An electrode for use in a plasma processing apparatus, comprising:
an electrode plate configured for use in a parallel-plate capacitively coupled plasma processing apparatus, the plasma processing apparatus including a processing chamber that forms a process space to accommodate a target substrate, a processing gas supply unit configured to supply a processing gas into the processing chamber, an exhaust unit connected to an exhaust port of the processing chamber to vacuum-exhaust gas from inside the processing chamber, a first electrode and a second electrode disposed opposite each other within the processing chamber, the first electrode being an upper electrode and the second electrode being a lower electrode, the second electrode being configured to support the target substrate via a mounting table, a first radio frequency (RF) power application unit configured to apply a first RF power to the first electrode, and a second RF power application unit configured to apply a second RF power to the second electrode, wherein the electrode plate is mountable to the first electrode, the electrode plate having a surface area that faces the second electrode when mounted to the first electrode, the surface area is substantially planar and includes a set of concentric rings protruding from the surface area, each concentric ring having a predetermined cross-sectional shape, and each concentric ring being spaced at a predetermined gap distance from an adjacent concentric ring.

2. The electrode of claim 1, wherein a cross-sectional height of each concentric ring is greater than about 0.5 millimeters and less that about 10.0 millimeters, and wherein a cross-sectional width of each concentric ring is greater than about 1.0 millimeters and less than about 20.0 millimeters, and wherein the predetermined gap distance is greater than about 1.0 millimeters and less that about 50.0 millimeters.

3. The electrode of claim 2, wherein the cross-sectional height of each concentric ring is greater than about 1.0 millimeters and less that about 3.0 millimeters, and wherein the cross-sectional width of each concentric ring is greater than about 2.0 millimeters and less than about 5.0 millimeters, and wherein the predetermined gap distance is greater than about 6.0 millimeters and less that about 20.0 millimeters.

4. The electrode of claim 1, wherein the first RF power is between 3 MHz and 300 MHz.

5. The electrode of claim 4, wherein the first RF power is between 30 MHz and 300 MHz.

6. The electrode of claim 1, wherein a cross-sectional height of each concentric ring, a cross-sectional width of each concentric ring, and the predetermined gap distance are all selected based on a diameter of the surface area of the electrode plate.

7. The electrode of claim 1, wherein a cross-sectional shape of each concentric ring is approximately triangular or trapezoidal such that side walls of each concentric ring project at an obtuse angle relative to the surface area.

8. The electrode of claim 1, wherein a cross-sectional shape of each concentric ring is approximately rectangular, and wherein the approximately rectangular cross-sectional shape has a round with a radius of between 0.2 millimeters and 1.0 millimeters, and has a fillet with a radius of between about 0.2 millimeters and 1.0 millimeters.

9. A plasma processing apparatus comprising:
a processing chamber that forms a process space to accommodate a target substrate;
a processing gas supply unit configured to supply a processing gas into the processing chamber;
an exhaust unit connected to an exhaust port of the processing chamber to vacuum-exhaust gas from inside the processing chamber;
a first electrode and a second electrode disposed opposite each other within the processing chamber, the first electrode being an upper electrode and the second electrode being a lower electrode, the second electrode being configured to support the target substrate via a mounting table, the first electrode including an electrode plate having a surface that faces the second electrode, the surface being substantially planar and having an external boundary of a predetermined shape, the surface including a set of elongated protrusions, each elongated protrusion extending a predetermined height from the surface, each elongated protrusion extending along the planar surface and around a center point of the first electrode, at least a portion of the elongated protrusions having an elongated shape substantially similar to the external boundary of the surface, the set of protrusions being positioned on the surface such that a portion of the protrusions are surrounded by at least one other protrusion, each given elongated protrusion being positioned a predetermined distance from an adjacent elongated protrusion; and
a first radio frequency (RF) power application unit configured to apply a first RF power to the first electrode.

10. The plasma processing apparatus of claim 9, wherein the predetermined height of each protrusion is greater than about 0.5 millimeters and less than about 10.0 millimeters, and wherein a cross-sectional width of each protrusion varies linearly in that a cross-sectional width at the surface of the electrode plate is greater than a cross-sectional width at the predetermined height from the surface, and wherein a gap distance between adjacent protrusions is greater than about 1.0 millimeters and less that about 50.0 millimeters.

11. The plasma processing apparatus of claim 9, wherein the predetermined height of each protrusion is greater than about 0.5 millimeters and less that about 10.0 millimeters, and wherein a cross-sectional width of each protrusion is greater than about 1.0 millimeters and less than about 20.0 millimeters, and wherein a gap distance between adjacent protrusions is greater than about 1.0 millimeters and less that about 50.0 millimeters.

12. The plasma processing apparatus of claim 11, wherein the predetermined height of each protrusion is greater than about 1.0 millimeters and less that about 3.0 millimeters, and wherein the cross-sectional width is greater than about 2.0 millimeters and less than about 5.0 millimeters, and wherein the gap distance between adjacent protrusions is greater than about 6.0 millimeters and less that about 20.0 millimeters.

13. The plasma processing apparatus of claim 9, wherein the first RF power is between 3 MHz and 300 MHz.

14. The plasma processing apparatus of claim 13, wherein the first RF power is between 30 MHz and 300 MHz.

15. The plasma processing apparatus of claim 9, wherein the predetermined height of each protrusion and the cross-sectional width of each protrusion are selected based on a frequency range of the first RF power such that a plasma generated via the plasma processing apparatus has a substantially uniform electron density across the first electrode.

16. The plasma processing apparatus of claim 9, wherein at least a portion of the set of elongated protrusions have a substantially rectangular elongated shape.

17. The plasma processing apparatus of claim 9, further comprising:
a second RF power application unit configured to apply a second RF power to the second electrode, wherein the electrode plate of the first electrode comprises a material selected from the group consisting of aluminum, silicon, and doped silicon.

18. A method of generating plasma for processing a substrate using a plasma processing apparatus, the plasma processing apparatus including a vacuum-evacuable processing chamber, a lower electrode disposed in the processing chamber and serving as a mounting table for a target substrate, an upper electrode disposed to face the lower electrode in the processing chamber, and a first radio frequency (RF) power supply connected to the upper electrode, the first RF power supply applying a first RF power to the upper electrode, the method comprising the steps of:
loading the target substrate into the processing chamber, and mounting the target substrate on the lower electrode;
evacuating an initial gas from the processing chamber;
supplying a processing gas into the processing chamber; and
generating a plasma of the processing gas by applying the first RF power to the upper electrode, the upper electrode having a surface area that faces the second electrode, the surface area being substantially planar and including a set of concentric rings protruding from the surface area, the set of concentric rings located at a predetermined spacing distribution, each concentric ring having a predetermined cross-sectional shape.

19. The method of generating plasma as in claim 18, wherein the plasma processing apparatus further includes a second RF power supply connected to the lower electrode, the second RF power supply applying a second RF power to the lower electrode, wherein the method further comprises: biasing the lower electrode by applying the second RF power to the lower electrode.

20. The method of claim 18, further comprising:
adjusting the first frequency power and adjusting pressure within the processing chamber such that the plasma generated has a specific electron density non-uniformity across the second electrode of less than about 10%.
